(19) United States
(12) Patent Application Publication
(10) Pub. No.: US 2009/0302321 A1
(43) Pub. Date: Dec. 10, 2009

(54) Thin Film Transistor Substrate and Method of Manufacturing the Same

(75) Inventors: Jeong-Min Park, Seoul (KR); Doo-Hee Jung, Seoul (KR); Dong-Ju Yang, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD, Suwon-si (KR)

(21) Appl. No.: 12/415,240

(22) Filed: Mar. 31, 2009

(30) Foreign Application Priority Data
Jun. 4, 2008 (KR) 2008-52741

(51) Int. Cl. H01L 29/78; H01L 21/336

(52) U.S. Cl. 257/66; 438/158; 257/E29.255; 257/E21.414

(57) ABSTRACT

A thin film transistor substrate includes; a substrate, an organic layer disposed on the substrate and including a trench formed by etching a predetermined region of an upper portion of the organic layer, a gate electrode disposed in the trench, an insulating layer disposed on the organic layer and the gate electrode, a semiconductor layer disposed on the insulating layer, a source electrode disposed on the semiconductor layer, and a drain electrode disposed on the semiconductor layer and spaced apart from the source electrode.

This application claims priority to Korean Patent Application No. 2008-52741, filed on Jun. 4, 2008, and all the benefits accruing therefrom under 35 U.S.C. §119, the contents of which in its entirety are herein incorporated by reference.

### BACKGROUND OF THE INVENTION

1. Field of the Invention

The present invention relates to a thin film transistor substrate and a method of manufacturing the same. More particularly, the present invention relates to a thin film transistor substrate having improved driving characteristics and a method of manufacturing the thin film transistor substrate.

2. Description of the Related Art

In general, a flat display apparatus displays images in response to external input signals. To this end, the flat display apparatus includes a first substrate and a second substrate disposed opposite to and coupled with the first substrate. At least one of the first and second substrates includes metal wires formed thereon to transmit the external input signals.

Lengths of the metal wires formed on the first and second substrates increase as an image display area of the flat display apparatus becomes larger. As a result, resistance of the metal wires increases since the lengths of the metal wires are lengthened, thereby causing distortion of electrical signals transmitted through the metal wires.

### BRIEF SUMMARY OF THE INVENTION

An exemplary embodiment of the present invention provides a thin film transistor substrate having improved driving characteristics. Another exemplary embodiment of the present invention also provides a method of manufacturing the thin film transistor substrate.

In an exemplary embodiment of the present invention, a thin film transistor substrate includes; a substrate, an organic layer disposed on the substrate and including a trench formed by etching a predetermined region of an upper portion of the organic layer, a gate electrode disposed in the trench, an insulating layer disposed on the organic layer and the gate electrode, a semiconductor layer disposed on the insulating layer, a source electrode disposed on the semiconductor layer, and a drain electrode disposed on the semiconductor layer and spaced apart from the source electrode.

In one exemplary embodiment, the organic layer may include a non-photosensitive organic material.

In one exemplary embodiment, the gate electrode includes; a first gate electrode layer including a seed layer of metal, and a second gate electrode layer disposed on the first gate electrode layer. In one exemplary embodiment, the second gate electrode layer may be formed by an electroless plating method.

In another exemplary embodiment of the present invention, a method of manufacturing a thin film transistor substrate includes disposing an organic layer on a substrate, forming a trench in the organic layer, disposing a gate electrode in the trench, disposing an insulating layer on the organic layer and the gate electrode, disposing a semiconductor layer on the insulating layer aligned with the gate electrode, and disposing a source electrode and a drain electrode, which is spaced apart from the source electrode, on the semiconductor layer.

In one exemplary embodiment, the trench is formed by disposing a photoresist layer on the organic layer, patterning the photoresist layer to expose a portion of the organic layer, and etching the exposed portion of the organic layer using the patterned photoresist layer as a mask.

In one exemplary embodiment, the gate electrode is disposed in the trench by disposing a first gate electrode layer on the photoresist layer and a bottom surface of the trench, removing the photoresist layer, and disposing a second gate electrode layer on the first gate electrode layer using an electroless plating method.

According to the above, the gate electrode formed in the trench of the organic layer has a relatively thick thickness, so that signals transmitted through the gate electrode may be prevented from being distorted or damaged. In addition, since the number of photolithography processes applied to form the trench decreases, a manufacturing cost may be reduced.

### BRIEF DESCRIPTION OF THE DRAWINGS

The above and other advantages of the present invention will become readily apparent by reference to the following detailed description when considered in conjunction with the accompanying drawings wherein:

FIG. 1 is a top plan view illustrating an exemplary embodiment of a thin film transistor substrate according to the present invention;

FIG. 2 is a cross-sectional view taken along line I-I′ of FIG. 1; and

FIGS. 3A to 3J are cross-sectional views illustrating an exemplary embodiment of a method of manufacturing a thin film transistor substrate according to the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present. In contrast, when an element is referred to as being “directly on” another element, there are no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “comprises” and/or “comprising,” or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

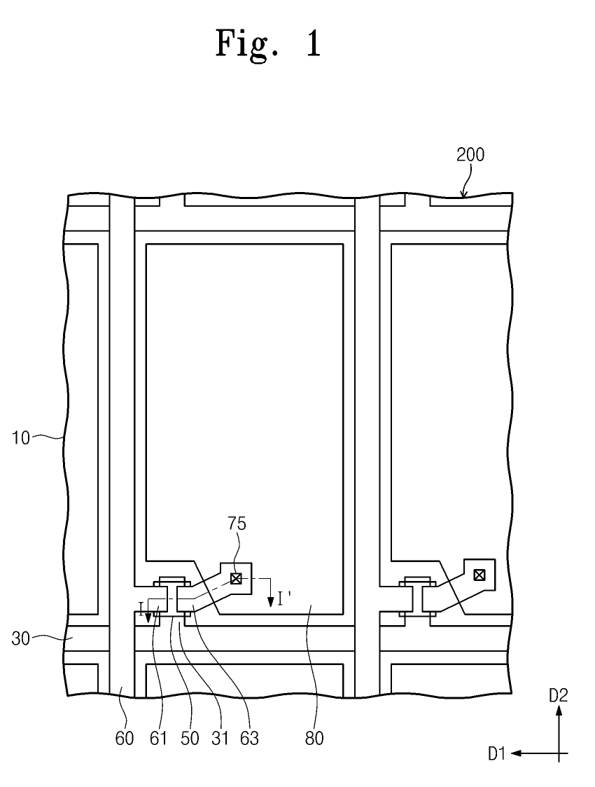

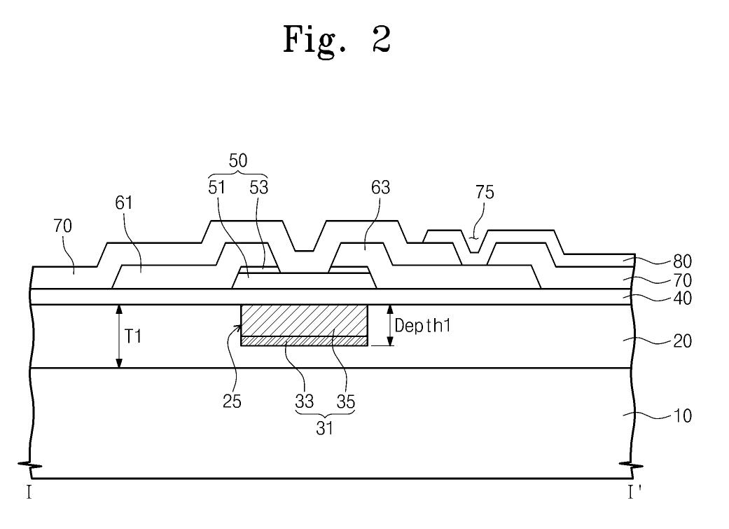

FIG. 1 is a top plan view illustrating an exemplary embodiment of a thin film transistor substrate according to the present invention, FIG. 2 is a cross-sectional view taken along line I-I′ of FIG. 1.

Referring to FIGS. 1 and 2, a thin film transistor substrate 200 includes a substrate 10, an organic layer 20 including a trench 25 formed therein, a gate line 30, a gate electrode 3 1, an insulating layer 40, a semiconductor layer 50, a data line 60, a source electrode 61, a drain electrode 63, a protective layer 70, and a pixel electrode 80.

In the present exemplary embodiment, the substrate 20 includes glass material, a plastic material, or other materials with similar characteristics and has a flat plate-like shape.

The organic layer 20 is disposed on the substrate 10, the organic layer 20 having a first thickness T1. In the present exemplary embodiment, he organic layer 20 includes a non-photosensitive organic material. In addition, in the present exemplary embodiment, the organic layer 20 includes a heat resistance material. Exemplary embodiments of the organic layer 20 may include a binder including a material including silane or silazane. The organic layer 20 may be relatively unaffected by a range of temperatures from about 300° Celsius to about 600° Celsius. Thus, the organic layer 20 may be relatively unaffected during a chemical vapor deposition (“CVD”) process that is performed at a temperature of about 370° Celsius. The organic layer 20 includes the trench 25, which may be formed by partially etching an upper portion of the organic layer 20. In the present exemplary embodiment, the trench 25 has a first depth Depth1 smaller than the first thickness T1 of the organic layer 20.

In the present exemplary embodiment, the trench 25 is formed by partially etching the upper portion of the organic layer 20 and extends in a first direction D1 along the substrate 10. Particularly, the trench 25 is recessed from the upper surface of the organic layer 20 and defined by two side surfaces and a bottom surface. The gate line 30 and the gate electrode 31 are disposed in the trench 25.

The gate line 30 extends in the first direction D1 along the first substrate 10 and the gate electrode 31 branches from the gate line 30. The gate line 30 and the gate electrode 31 face the substrate 10 while interposing the organic layer 20 therebetween. As discussed above, the gate line 30 and the gate electrode 3 are formed in the trench 25. Exemplary embodiments of the gate line 30 and the gate electrode 31 may include aluminum (Al), molybdenum (Mo), copper (Cu), silver (Ag), or an alloy thereof and may have a single layer structure or a multi-layer structure. In the present exemplary embodiment, the gate line 30 and the gate electrode 31 have the same structure and are composed of the same metal material, and therefore the gate electrode 31 shown in FIG. 2 will be described as an example of both the gate line 30 and the gate electrode 31.

In the present exemplary embodiment, the gate electrode 31 includes a first gate electrode layer 33 and a second gate electrode layer 35. Exemplary embodiments of the first gate electrode layer 33 may include molybdenum, and exemplary embodiments of the second gate electrode layer 35 may include copper. In addition, in the present exemplary embodiment, the gate electrode 31 may have a thickness substantially equal to the first depth Depth1 of the trench T1, so that signals transmitted through the gate line 30 and the gate electrode 31 may be prevented from being distorted.

The insulating layer 40 is formed on the organic layer 20, the gate line 30, and the gate electrode 31. In order to insulate the gate line 30 and the gate electrode 31 from other signal lines, such as other gate lines or data lines, the insulating layer 40 may be made of an insulating material, exemplary embodiments of which include silicon nitride (“SiNx”), silicon oxide (“SiOx”), or other materials having similar characteristics.

The semiconductor layer 50 is formed on the insulating layer 40 corresponding to the gate electrode 31. In the present exemplary embodiment, the semiconductor layer 50 includes an active layer 51 and an ohmic contact layer 53. The active layer 51 is formed on the insulating layer 40 and exemplary embodiments thereof may be made of amorphous silicon, polysilicon, or crystalline silicon. The ohmic contact layer 53 is formed on the active layer 51 and may be formed by doping a silicon layer with impurities. In one exemplary embodiment, the ohmic contact layer 53 may include impurity-doped amorphous silicon, impurity-doped polysilicon, or other materials having similar characteristics.

The data line 60 is disposed substantially perpendicular to the gate line 30 and is formed on the insulating layer 40. The data line 60 and the gate line 30 substantially surround a pixel area.

The source electrode 61 branches from the data line 60 and is formed on the organic layer 40 and the semiconductor layer 50. The source electrode 61 makes contact with a portion of the ohmic contact layer 53, so that the source electrode 61 may be electrically connected to the active layer 51 through the ohmic contact layer 53.

The drain electrode 63 is spaced apart from the source electrode 61 and formed on the insulating layer 40 and the semiconductor layer 50. Particularly, the drain electrode 63 makes contact with another portion of the ohmic contact layer 53, thereby electrically connecting the drain electrode 63 to the active layer 51 through the ohmic contact layer 53.

The protective layer 70 is formed above the substrate 10 to cover the semiconductor layer 50, the data line 60, the source electrode 61, and the drain electrode 63 disposed thereunder. The protective layer 70 insulates the semiconductor layer 50, the data line 60, the source electrode 61 and the drain electrode 63 from other signal lines and protects the semiconductor layer 50, the data line 60, the source electrode 61 and the drain electrode 63 from external impacts. The protective layer 70 is provided with a contact hole 75 formed therethrough to expose a portion of the drain electrode 63.

The pixel electrode 80 is formed on the protective layer 70 and electrically connected to the drain electrode 63 through the contact hole 75. In one exemplary embodiment, the pixel electrode 80 may be formed from a transparent conductive material such that light provided from a lower portion thereof transmits through the pixel electrode 80. Exemplary embodiments of the transparent conductive material may include indium tin oxide (“ITO”), indium zinc oxide (“IZO”), or other materials with similar characteristics.

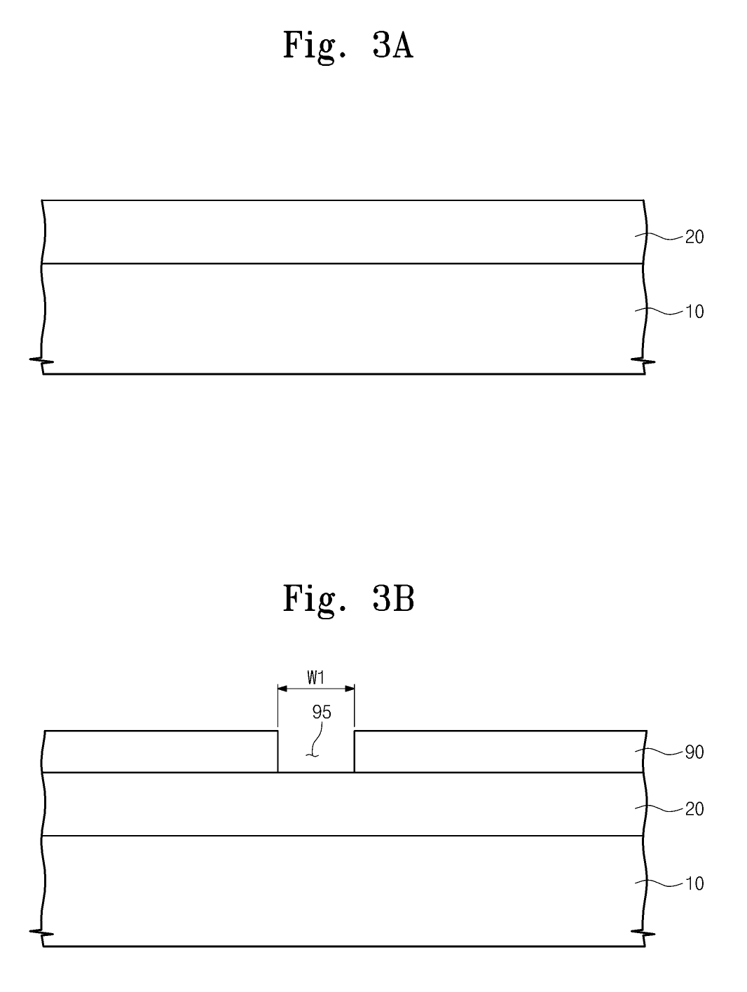

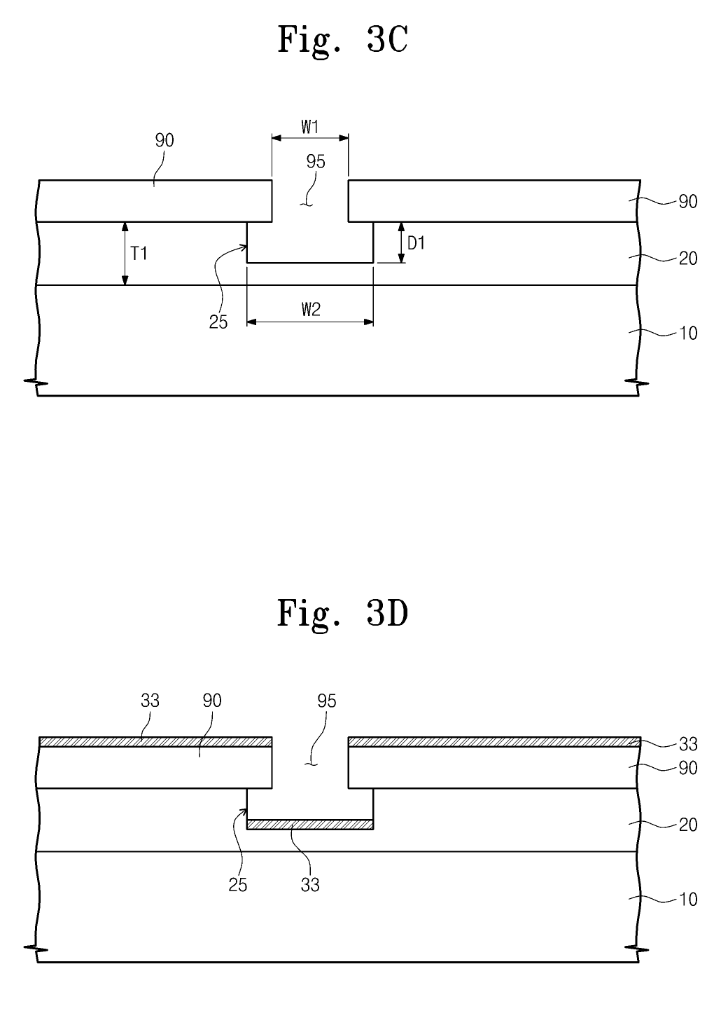

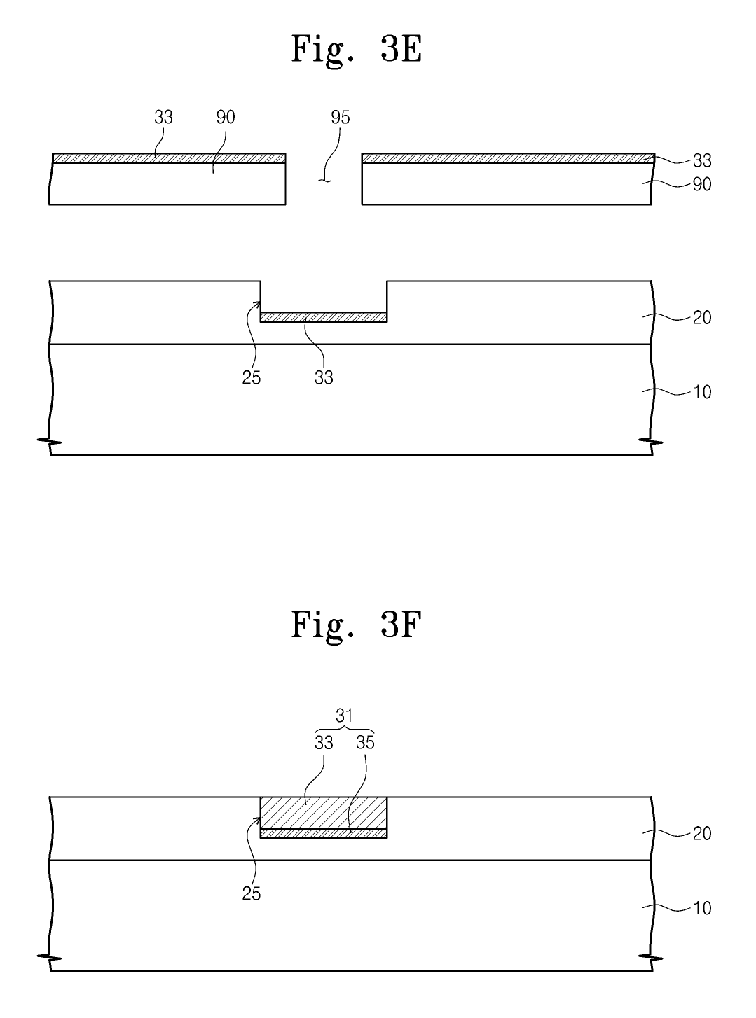

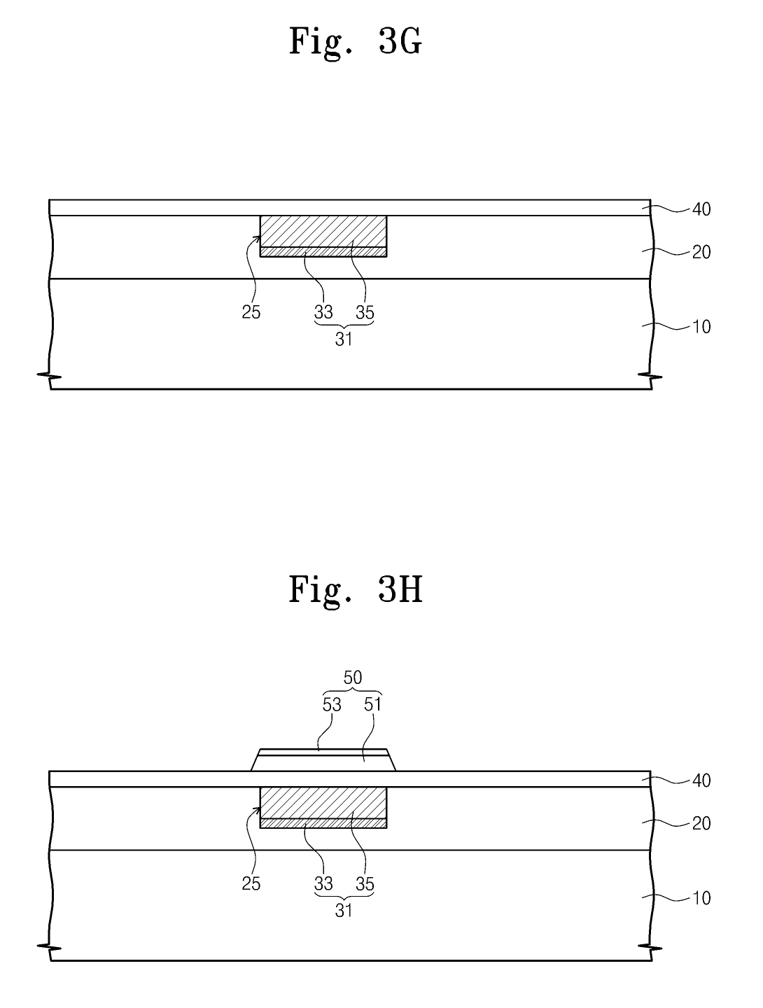

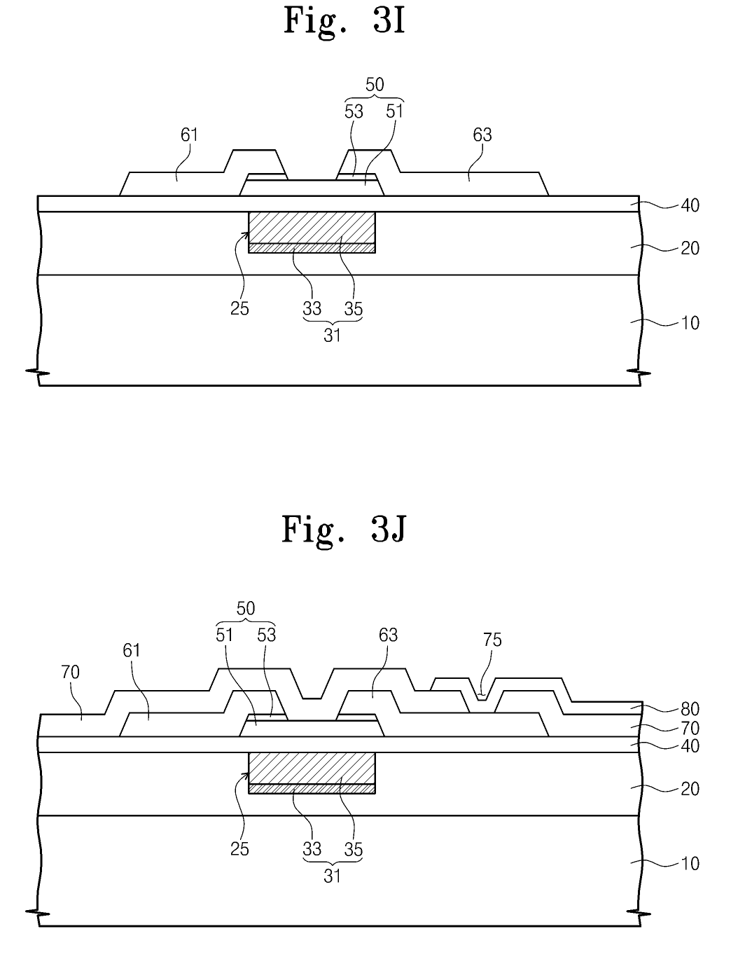

Hereinafter, an exemplary embodiment of a method of manufacturing a thin film transistor substrate is described with reference to FIGS. 3A to 3J.

FIGS. 3A to 3J are cross-sectional views illustrating an exemplary embodiment of a method of manufacturing an exemplary embodiment of a thin film transistor substrate according to the present invention.

Referring to FIG. 3A, an organic material is coated on the substrate 10, exemplary embodiments of which may be made of glass or plastic, to form the organic layer 20. In the present exemplary embodiment, the organic material is substantially non-photosensitive and includes the binder including silane or silazane. In order to prevent non-reacted material from remaining in the organic material, in one exemplary embodiment the organic layer 20 is heat-treated at a temperature of about 220° Celsius to about 300° Celsius.

Then, referring to FIG. 3B, a photoresist layer 90 is formed by coating a photoresist on the organic layer 20. The photoresist is then patterned by an exposure and development process in order to form the photoresist layer 90 having an opening 95 formed therethrough. In one exemplary embodiment, the photoresist may be a negative type photoresist wherein portions which have been irradiated by light remain after a developing process. In such an exemplary embodiment, the portion through which the opening 95 is formed is an area onto which the light is not irradiated, and the portion is removed by the development process. The opening 95 has a first width W1 and a portion of the organic layer 20 is exposed through the opening 95 having the first width W1.

Meanwhile, although not shown in FIGS. 3A to 3J, in order to prevent the photoresist layer 90 from being damaged, the opening 95 may be formed such that an angle between an upper surface of the photoresist layer 90 and side surfaces of the photoresist layer 90, which define the opening 95, increases. Particularly, because the photoresist layer 90 is used as a mask for a following etch process to be discussed in more detail below, portions of the photoresist layer 90 that are adjacent to the opening 95 may be damaged when the angle between the upper surface and side surfaces is relatively small.

Referring to FIG. 3C, the portion of the organic layer 20 exposed through the photoresist layer 90 is etched using the photoresist layer 90 as an etch mask, so the trench 25 is formed. More particularly, in one exemplary embodiment the substrate 10 on which the organic layer 20 and the photoresist layer 90 are formed is loaded into a chamber of an etching apparatus, and the organic layer 20 exposed through the opening 95 of the photoresist layer 90 is etched using an etching gas including oxygen (O₂). In an exemplary embodiment wherein an etching gas including fluorine (F) is added to the etching gas of oxygen and a pressure in the chamber increases, a time during which activated materials remain in the chamber may be lengthened. In addition, exemplary embodiments include configurations wherein the organic layer 20 may be etched by an etching apparatus using a plasma-enhanced mode. As a result, the organic layer 20 is undercut beneath the opening 95 of the photoresist layer 90, thereby forming the trench 25. Thus, the trench 25 has a second width W2 larger than the first width W1 of the opening 95 (i.e., W2>W1), and the trench 25 has the first depth Depth1 such that the substrate 10 is not exposed therethrough. That is, the first depth Depth1 of the trench 25 is smaller than the first thickness T1 of the organic layer 20 (i.e., D1<T1).

Referring to FIG. 3D, a seed layer of metal including molybdenum (Mo) is coated on upper surface of the photoresist layer 90 and the bottom surface of the trench 25 to form the first gate electrode layer 33. In one exemplary embodiment, the seed layer may be formed through a sputtering method.

Then, referring to FIG. 3E, the photoresist layer 90 formed on the organic layer 20 is removed. Particularly, in one exemplary embodiment the photoresist layer 90 is separated from the organic layer 20 by a lift-off method using a stripping solution or an external force, so that the first gate electrode layer 33 formed on the photoresist layer 90 may be removed together with the photoresist layer 90. Alternative exemplary embodiments include other methods for removing the photoresist layer 90 and the first gate electrode layer 33 formed thereon as would be apparent to one of ordinary skill in the art.

Referring to FIG. 3F, the second gate electrode layer 35 is formed on the first gate electrode layer 33. In one exemplary embodiment, the second gate electrode layer 35 is formed using an electroless plating method. In detail, the electroless plating method uses an electroless plating solution containing a reducing agent and uses catalysis to deposit metal ions for forming the second gate electrode layer 35 on the first gate electrode layer 33. The metal deposited by the electroless plating method may have a more uniform surface than that of a metal deposited by an electroplating method. Thus, the gate electrode 31 including the first gate electrode layer 33 including molybdenum (Mo) and the second gate electrode layer 35 including copper (Cu) is formed in the trench 25. In addition, the gate line 30, which is electrically connected to the gate electrode 31, is formed by substantially the same processes as the gate electrode 31, so that the gate line 30 may have the same double layer structure of the first and second gate electrode layers 33 and 35.

Referring to FIG. 3G, the insulating layer 40 is formed on the organic layer 20 and the second gate electrode layer 35. In one exemplary embodiment, an inorganic material, such as silicon nitride (“SiNx”), silicon oxide (“SiOx”), and other materials having similar characteristics, is deposited on the organic layer 20 and the second gate electrode layer 35 to form the insulating layer 40. In one exemplary embodiment, the insulating layer 40 is formed by a CVD process that is conducted at a temperature of about 370° Celsius. During forming the insulating layer 40, the organic layer 20 may be heated to about 320° Celsius, however the organic layer 20 may be prevented from being damaged since the organic layer 20 includes the heat resistance material as discussed above.

Referring to FIG. 3H, a semiconductor material is deposited on the organic layer 40 and patterned to form the semiconductor layer 50 including the active layer 51 and the ohmic contact layer 53. Particularly, in one exemplary embodiment the amorphous silicon layer and the impurity-doped amorphous silicon are sequentially formed on the insulating layer 40. Then, the amorphous silicon layer and the impurity-doped amorphous silicon are patterned to form the semiconductor layer 50 including the active layer 51 and the ohmic contact layer 53. In one exemplary embodiment, the semiconductor material may include polysilicon or crystalline silicon.

Next, referring to FIG. 3I, the metal material for the data wiring is deposited on the organic layer 40 and the semiconductor layer 50 and patterned to form the source electrode 61 and the drain electrode 63. Particularly, in one exemplary embodiment the metal material is formed on the organic layer 40 and the semiconductor layer 50 by a sputtering method. The metal material is patterned to form the source electrode 61, the drain electrode 63, and the data line 60. In one exemplary embodiment the metal material may be patterned by a photolithographic method. During the etching process of the metal material, a portion of the ohmic contact layer 53, which is exposed through between the source electrode 61 and the drain electrode 63, is etched to form a channel area in the active layer 51.

Referring to FIG. 3J, the protective layer 70 is formed over the substrate 10 after forming the source and drain electrodes 61 and 63. In one exemplary embodiment, the protective layer 70 is formed using an insulating material. Then, a portion of the protective layer 70 is etched, so that the contact hole 75 is formed through the protective layer 70, through which a portion of the drain electrode 63 is exposed. The pixel electrode 80 is formed on the protective layer 80 and is electrically connected to the drain electrode 63 through the contact hole 75. Exemplary embodiments include configurations wherein the protective layer 70 may include at least one of an organic material and inorganic material. In addition, the pixel electrode 80 may includes the transparent conductive material, exemplary embodiments of which include indium tin oxide (“ITO”), indium zinc oxide (“IZO”), and other materials having similar characteristics.

According to the above, the gate electrode formed in the trench of the organic layer has a relatively thick thickness, so that signals transmitted through the gate electrode may be prevented from being distorted or degraded.

In addition, since only a small number of photolithography processes are applied to form the trench and the plating method is used to form the gate electrode, a manufacturing cost may be reduced.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A thin film transistor substrate comprising:
a substrate;
an organic layer disposed on the substrate and including a trench formed by etching a predetermined region of an upper portion of the organic layer;
a gate electrode disposed in the trench;
an insulating layer disposed on the organic layer and the gate electrode;
a semiconductor layer disposed on the insulating layer;
a source electrode disposed on the semiconductor layer; and
a drain electrode disposed on the semiconductor layer and spaced apart from the source electrode.

2. The thin film transistor substrate of claim 1, wherein the organic layer comprises a non-photosensitive organic material.

3. The thin film transistor substrate of claim 2, wherein the organic layer comprises a binder including at least one of silane and silazane.

4. The thin film transistor substrate of claim 1, wherein the gate electrode comprises:
a first gate electrode layer including a seed layer of metal; and
a second gate electrode layer disposed on the first gate electrode layer.

5. The thin film transistor substrate of claim 4, wherein the first gate electrode layer comprises molybdenum and the second gate electrode layer comprises copper.

6. The thin film transistor substrate of claim 1, wherein the organic layer is disposed between the gate electrode and the substrate in the trench.

7. The thin film transistor substrate of claim 1, further comprising a pixel electrode electrically connected to the drain electrode.

8. A method of manufacturing a thin film transistor substrate, comprising:
forming an organic layer on a substrate;
forming a trench in the organic layer;
forming a gate electrode in the trench;
forming an insulating layer on the organic layer and the gate electrode;
forming a semiconductor layer on the insulating layer aligned with the gate electrode; and
forming a source electrode and a drain electrode, which is spaced apart from the source electrode, on the semiconductor layer.

9. The method of claim 8, wherein the trench is formed by:
forming a photoresist layer on the organic layer;
patterning the photoresist layer to expose a portion of the organic layer; and
etching the exposed portion of the organic layer using the patterned photoresist layer as a mask.

10. The method of claim 9, wherein the exposed portion of the organic layer is undercut when the organic layer is etched.

11. The method of claim 8, wherein the gate electrode is disposed in the trench by:
forming a first gate electrode layer on the photoresist layer and a bottom surface of the trench;
removing the photoresist layer; and
forming a second gate electrode layer on the first gate electrode layer using an electroless plating method.

12. The method of claim 8, further comprising heat-treating the organic layer after the organic layer is disposed on the substrate.

13. The method of claim 8, wherein the organic layer comprises a non-photosensitive organic material.

14. The method of claim 13, wherein the organic layer comprises a binder including at least one of silane and silazane.

15. The method of claim 8, further comprising:
forming a protective layer on the source electrode and the drain electrode; and
forming a contact hole by removing a portion of the protective layer; and
forming a pixel electrode connected to the drain electrode via the contact hole.
